(19) United States
(12) Patent Application Publication
(10) Pub. No.: US 2026/0184045 A1
(43) Pub. Date: Jul. 2, 2026

(54) COATED GLASS ASSEMBLY FOR IMAGING

(71) Applicant: TESLA, INC., Austin, TX (US)

(72) Inventors: Christos Gougoussis, Fremont, CA (US); Michael Pilliod, Austin, TX (US); William S, Sweney, Oakland, CA (US); Stefan Kuzmanovski, Richmond, CA (US); Dante Lamastra, Austin, TX (US); Aditya Suresh Murthy, Dublin, CA (US); Nicolas Clift, Austin, TX (US); Matthew Robert Rocchio, Campbell, CA (US)

(21) Appl. No.: 19/131,864

(22) PCT Filed: Jan. 16, 2024
(86) PCT No.: PCT/US2024/011644

§ 371 Date: May 21, 2025

Related U.S. Application Data
(60) Provisional application No. 63/439,514, filed on Jan. 17, 2023.

(51) Int. Cl. B32B 17/10; H04N 23/52; H04N 23/55; H04N 23/57; H10F 39/00

(52) U.S. Cl. CPC B32B 17/10045; B32B 17/10761; B32B 17/10779; H04N 23/52; H04N 23/55; H04N 23/57; H10F 39/805; H10F 39/811; B32B 2250/03; B32B 2255/20; B32B 2305/345; B32B 2307/202; B32B 2307/412; B32B 2559/00; B32B 2605/00

(57) ABSTRACT

A coated glass stack positioned in front of an image sensor can include a glass insert coated with a transparent metallic layer and conductive traces. The glass insert can also be coated with an anti-reflective layer to mitigate light loss through the metallic layer. A coated glass stack installed with a low angle may include a cutout area in front of the image sensor having a different composition than the rest of the glass stack. The coated glass stack can also include a vertical window between the coated glass stack and the image sensor. The coated glass stack may also include a glareshield in front of the image sensor and below the coated glass stack.

### CROSS-REFERENCE TO RELATED APPLICATION

This application claims priority to U.S. Prov. Patent App. No. 63/439,514 titled “COATED GLASS ASSEMBLY FOR IMAGING” and filed on Jan. 17, 2023, the disclosure of which is hereby incorporated herein by reference in its entirety.

### TECHNICAL FIELD

The present application relates to a coated glass assembly. More particularly, the coated glass can be used on glass in front of one or more cameras.

### BACKGROUND

An imaging sensor (e.g., a camera) may be positioned behind a glass or glass stack that shields the imaging sensor from the ambient environment. However, due to the thickness, ambient temperature, installation angle of the glass, and many other factors, the glass may impair the camera's imaging quality through the glass. A heater can be implemented on a glass to defog or deice but may also create artifacts in the images of a camera behind the glass.

### SUMMARY

The disclosure relates generally to a coated glass assembly. More specifically, various embodiments of this disclosure relate to coated glass in front of a camera.

An aspect is directed to a coated glass assembly configured to be positioned in front of an image sensor. The coated glass assembly includes a glass stack, a glass insert coupled to the glass stack via transparent adhesive, and a transparent conductive layer coated to the glass insert. The glass insert is configured to be positioned in front of the image sensor.

A variation of the aspect above is, wherein the glass stack comprises an outer glass, one or more interlayers, and an inner glass.

A variation of the aspect above further comprises an anti-reflective coating on the glass insert.

A variation of the aspect above further comprises conductive traces configured to provide power to the transparent conductive layer and heat up the transparent conductive layer.

A variation of the aspect above is, wherein the transparent conductive layer comprises indium tin oxide.

Another aspect is directed to a coated glass assembly configured to be positioned in front of an image sensor. The coated glass assembly includes a glass stack positioned at an angle from a vertical plane, the vertical plane being substantially parallel to a lens of the image sensor. The coated glass assembly further includes a first area in the glass stack having a different composition than a second area of the glass stack. The coated glass assembly also includes a glareshield extending from a first point proximate a lower end of the first area to a second point proximate the image sensor, and a window separator positioned parallel to the vertical plane, between the glass stack and the image sensor.

A variation of the aspect above is, wherein the glass stack in the second area comprises a first outer glass, a first set of one or more interlayers, and a first inner glass.

A variation of the aspect above is, wherein the glass stack in the first area does not comprise the first set of one or more interlayers and the first inner glass.

A variation of the aspect above is, wherein the glass stack in the first area comprises a second inner film coupled to the first outer glass via a transparent adhesive.

A variation of the aspect above is, wherein the glass stack in the first area comprises a second outer glass different from the first outer glass, a second set of one or more interlayers different from the first set of one or more interlayers, and a second inner glass different from the first inner glass.

### BRIEF DESCRIPTION OF THE DRAWINGS

The present disclosure is described with reference to the accompanying drawings, in which like reference characters reference like elements, and wherein:

FIG. 1A is a perspective view of a glass insert of a coated glass assembly according to an embodiment of the present disclosure.

FIG. 1B is a cross-sectional view of a coated glass assembly according to another embodiment of the present disclosure.

FIG. 1C is a cross-sectional close-up view of interlayers of the coated glass assembly from FIG. 1B.

FIG. 2A is a cross-sectional view of a coated glass assembly according to another embodiment of the present disclosure.

FIG. 2B is a cross-sectional view of a coated glass assembly according to another embodiment of the present disclosure.

FIG. 2C is a cross-sectional view of a coated glass assembly according to another embodiment of the present disclosure.

FIG. 3A is a cross-sectional view of an angled coated glass assembly according to another embodiment of the present disclosure.

FIG. 3B is a cross-sectional view of the angled coated glass assembly from FIG. 3A with additional inner film or glass and adhesive layer.

FIG. 4 is a cross-sectional view of an angled coated glass assembly according to another embodiment of the present disclosure.

FIG. 5 illustrates a windshield of a vehicle which includes a glass insert according to the techniques described herein.

### DETAILED DESCRIPTION

Generally described, one or more aspects of the present disclosure relate to a coated glass assembly. In certain embodiments, this disclosure relates to a coated glass insert positioned in front of a vehicle camera or multiple vehicle cameras. As an example, the vehicle camera may be positioned such that it is pointing in a forward direction and images a real-world environment. For this example, the vehicle camera may be behind a windshield of the vehicle. Specifically, the coated glass can include an indium tin oxide (ITO) coating which acts as a heater to remove ice and/or fog and improve a view through the coated glass. The coated glass can also include an anti-reflective coating to enhance imaging quality and reduce artifacts caused by, for example, diffraction and light loss through the glass.

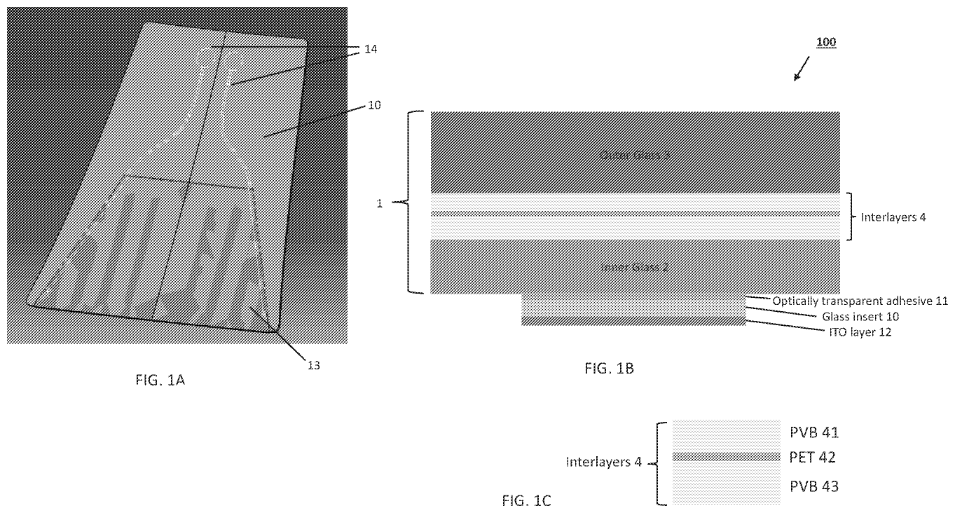

As shown in FIGS. 1A-1C, an embodiment of a coated glass assembly 100 according to this disclosure can include a glass stack 1 and a transparent substrate or glass insert 10 coupled to the glass stack 1. In some embodiment, the glass insert 10 can be made of any transparent material, e.g., PET. The glass insert 10 may optionally be cold bent (e.g., cold being the insert 10) to a shape or contour of the glass stack 1. In some embodiments, the glass stack 1 can include an inner glass 2, an outer glass 3, and one or more interlayers 4 positioned between the inner glass 2 and the outer glass 3. In some embodiments, the glass stack 1 can include Soda-lime glass. In some embodiments, the interlayers 4 can be formed of any desirable materials (e.g., plastic, PVB, etc.). In some embodiments, the interlayers 4 can include a PVB layer 41, a PET layer 42, and a PVB layer 43 as shown in FIG. 1C. When the glass stack 1 is installed on a vehicle as a windshield, for example, the inner glass 2 can be configured to face an inner space of the vehicle, and the outer glass 3 can be configured to face an outside environment of the vehicle.

In certain embodiments, the glass insert 10 can be coupled to an inner side of the glass stack 1, proximate the inner glass 2. In some embodiments, the glass insert 10 can be coupled to the glass stack 1 via optically transparent adhesive 11 (e.g., OCA, PVB, and etc.). In some embodiments, the glass insert 10 can be at least partially coated with an ITO layer 12. In some embodiments, the glass insert 10 can have an ITO coated area 13 located only within a field of view (FOV) of a camera (or FOVs of multiple cameras) (e.g., the FOV may be the trapezoid shape on the glass insert). In certain embodiments, the glass insert 10 can further include a set of busbars 14. In certain embodiments, the set of busbars 14 comprise a conductive silver paste. In some embodiments, the set of busbars 14 can be fired onto the glass insert 10 on an inner side of the glass insert 10. In some embodiments, the set of busbars 14 can be positioned along or outside the FOVs of the one or more cameras. In some embodiments, each set of busbars 14 can extend on each side of the ITO coated area 13 at least from a bottom end of the ITO coated area 13 to a top end of the ITO coated area 13. In some embodiments, the set of busbars 14 can extend from a bottom end of the glass insert 10 towards a top end of the glass insert 10.

In accordance with various embodiments of this disclosure, the set of busbars 14 can be connected to power and conduct electricity to the ITO layer 12 in order to generate heat in the ITO coated area 13. In some embodiments, the busbars 14 can be fired onto the glass insert 10. Heater connectors may then be soldered to the busbars 14 in order to power the heater. The use of ITO coating as the heater can avoid having non-uniform heating elements (e.g., heating wires) that may produce artifacts in the camera's images. In certain embodiments, the coated glass assembly 100 can include windshield bracketry, the one or more cameras, and other related components bonded onto the glass insert 10.

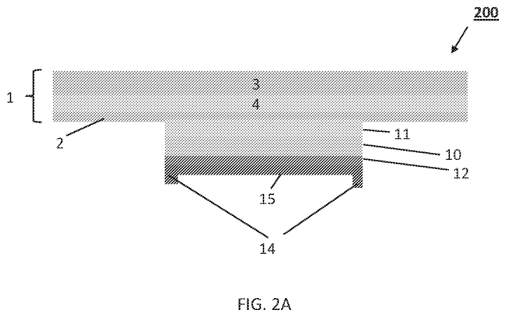

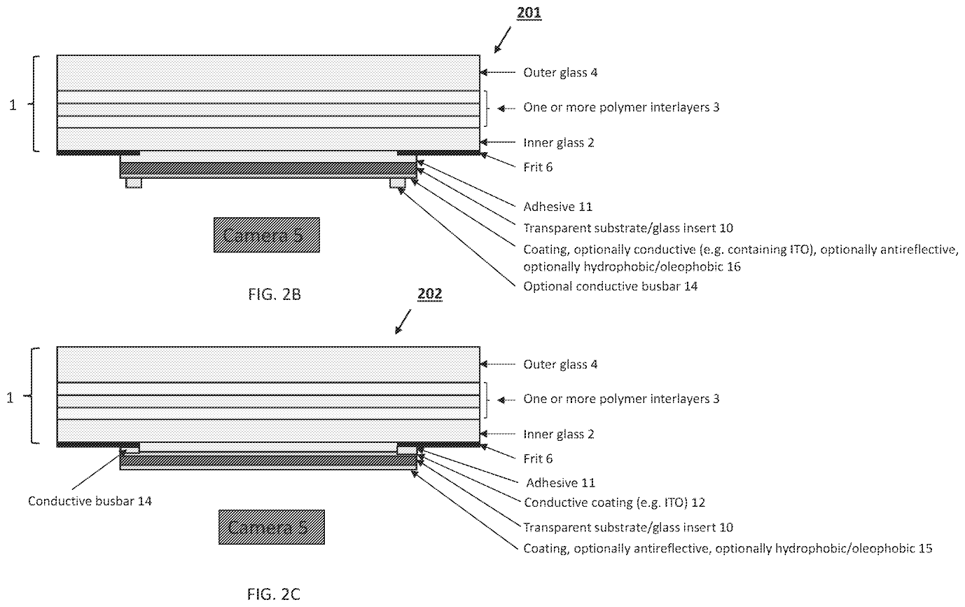

Another embodiment of a coated glass assembly 200 according to this disclosure is shown in FIG. 2A. Unless otherwise noted, the components of FIGS. 2A-2C may be the same as or generally similar to like-numbered components of FIGS. 1A-1C and may function or operate in a generally similar manner. In various embodiments, the coated glass assembly 200 can similarly include a glass stack 1 and a glass insert 10 coupled to the glass stack 1 via optically transparent adhesive 11. In some embodiments, the glass insert 10 can be chemically strengthened (e.g., conducting ion exchange in a salt bath, typically a potassium nitrate salt bath). In some embodiments, the glass insert 10 can similarly include a transparent metallic coating 12 (e.g., ITO) on an inner side of the glass insert 10. In some embodiments, the glass insert 10 can further include conductive traces or conductive busbars 14 disposed along sides of the transparent metallic coating 12. In some embodiments, the coated glass assembly 200 can further include a coating 15 (e.g., an anti-reflective (AR) layer) coated onto the metallic coating 12 also on the inner side of the glass insert 10. The coating 15 can configured to be anti-reflective (AR), hydrophobic, and/or oleophobic.

FIGS. 2B and 2C show additional embodiments of a coated glass assembly disclosed herein. In some embodiments, as shown in FIG. 2B, instead of two separate layers of coatings 12 and 15, a coated glass assembly 201 can include one coating 16 that can optionally be configured to be conductive (e.g., containing ITO), anti-reflective, hydrophobic, and/or oleophobic. In some embodiments, for example, if the coating 16 is configured to be conductive, the glass stack 201 can include conductive busbar 14 to operate, in connection with the conductive coating 16, as a heater.

FIG. 2C shows a coated glass assembly 202 having a transparent metallic coating 12 disposed on a first side of the glass insert 10. In certain embodiments, the coated glass assembly can further include a coating 15 coated on a second side of the transparent substrate, opposite to the first side. In some embodiments, the coating 15 may be an AR layer. In some embodiments, the coating may optionally be configured to be hydrophobic and/or oleophobic.

In various embodiments, the transparent metallic coating disclosed herein can have a thickness of approximately 5 nm and contain at least 50% silver. In some embodiments, the transparent metallic coating can have a thickness of between about 5 to about 50 nm and contain at least 50% silver. In some embodiments, the transparent metallic coating can have a thickness of approximately 50 nm. Alternatively, in certain embodiments, the transparent metallic coating can be formed of ITO having a thickness of between about 50 to about 400 nm. In certain embodiments, the transparent metallic coating can be formed of ITO having a thickness of approximately 50 nm. In certain embodiments, the transparent metallic coating can be formed of ITO having a thickness of approximately 400 nm. The metallic coating may be connected to power and act as a heater to remove ice or fog.

In some embodiments, the AR layer can be formed of at least one layer of silica having a thickness of between 50 to 250 nm and a porosity between 30 to 70%. In some embodiments, the AR layer can be formed of SiO2 having a thickness of approximately 180 nm and a porosity of 50% porous. The AR coating can reduce light lost through the glass stack and provide hydrophobic, hydrophilic, and anti-smudge functions. When used with the metallic coating, the AR coating may mitigate the additional light lost through the metallic coating layer.

In some embodiments, the coated glass assembly 201 or 202 may further include a frit 6 configured to hide the transition between an area of the glass stack 1 with the glass insert 10 attached and an area of the glass stack 1 without the glass insert 10 when viewed from an outer side of the glass stack 1. In some embodiments, the frit 6 can be disposed on an inner side of the glass stack 1 and around the glass insert 10. In some embodiments, the frit 6 can be made of ceramic or any other decorative material. In some embodiments, the frit 6 can be in black.

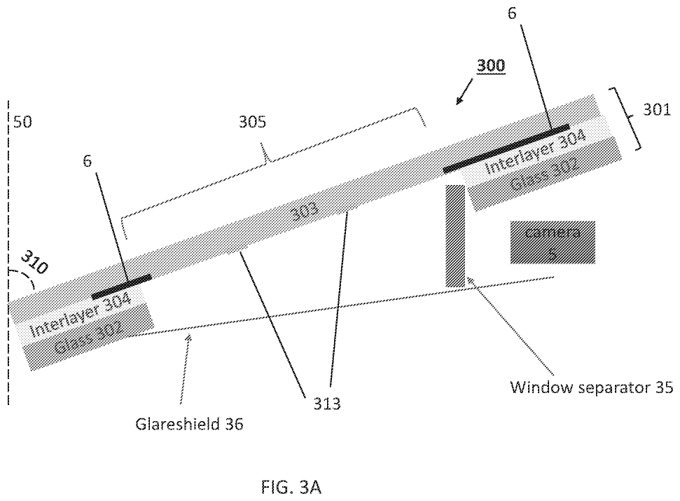

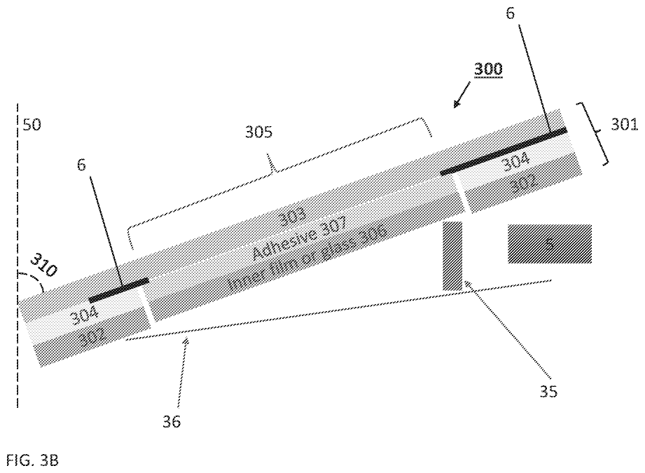

FIGS. 3A-B show another embodiment of a coated glass assembly 300 according to this disclosure. The coated glass assembly 300 can similarly include a glass stack 301 having an inner glass 302, an outer glass 303, and interlayers 304. The glass stack 301 may be positioned at an angle 310 relative to a vertical plane 50 substantially parallel to a lens of a camera 5. Imaging of the camara 5 directly through the glass stack 301 may be poor because of high distortion and low light transmission through the glass stack 301 at the angle 310. The angle 310 can be greater than 45°. Various features disclosed below may, in addition to providing other advantages, mitigate camera imaging distortion resulting from an angled orientation of the glass in front of the camera (e.g., a low-angle windshield of a vehicle).

In various embodiments, the glass stack 301 can have a cutout area 305 around a FOV of the camera 5. For example, in the cutout area 305, the glass stack 301 does not include the inner glass 302 and the interlayers 304. The outer glass 303 can have a high light transmission rate of greater than 80%. In some embodiments, the outer glass 303 may include silver traces 313 positioned in the cutout area 305 for heating. In some embodiments, the outer glass 303 may also be AR treated (e.g., coated with an AR layer). In some embodiments, the coated glass assembly 300 can further include a glareshield 36 extending from a first point proximate a lower end of the cutout area 305 to a second point proximate the camera 5. The glareshield 36 may be configured to prevent sun light reflecting into the camera 5 and degrading imaging quality. In some embodiments, the glareshield 36 may be coated with dark paint to prevent glare.

In accordance with various embodiments, the camera 5 may be mounted to a coated glass assembly through a bracket. In some embodiments, the camera bracket can be mounted to the inner surface of the inner glass. In some embodiments, the camera 5 may be mounted to the glass stack 301 through a bracket mounted to an inner surface of the inner glass 302, the bracket positioned outside the cutout area 305 and/or the FOV of the camera 5.

The coated glass assembly 300 can further include a transparent window separator 35 positioned parallel to the vertical plane 50, between the glass stack 301 and the camera 5. In some embodiments, the window separator 35 can be substantially flat. In some embodiments, the window separator 35 can be AR treated (e.g., coated with an AR layer). In some embodiments, the window separator 35 can also be coated with a low-emissive or conductive coating (e.g., ITO layer) for heating. The window separator 35 may keep hot air away from the camera when sun light heats up the glass stack 301. The window separator 35 can be highly transmissive, even when heated by sunlight or a heater, due to its vertical orientation. The window separator 35, in combination with the glareshield 36, may also trap air heated by sunlight and prevent the hot air from heating the camera 5.

As shown in FIG. 3B, in certain embodiments, the coated glass assembly 300 can also include an inner film/glass layer 306 coupled to the outer glass 303 via a layer of transparent adhesive 307. In some embodiments, the inner film/glass layer 306 may be AR coated. In some embodiments, the AR coating is formed of at least one layer of low refractive index material (e.g., refractive index n in a range of approximately 1.2 to 1.38). In some embodiments, the AR layer can have a thickness of between approximately 140 to 200 nm. In some embodiments, the inner film/glass layer 306 may also be coated with a transparent conductive layer (e.g., ITO) for heating. In some embodiments, the adhesive layer 307 can be UV-cured to reduce distortion caused by the layer. In some embodiments, heating element can also be inserted in the adhesive layer 307.

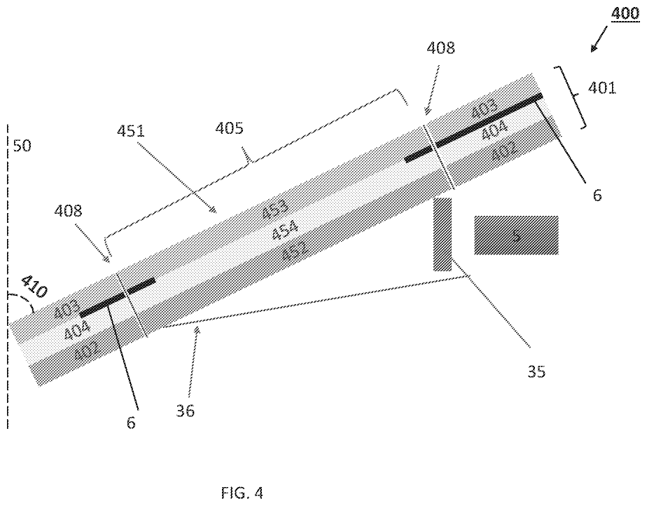

Yet another embodiment of a coated glass assembly according to this embodiment may have a modular design. As shown in FIG. 4, the glass stack 401 may similarly be positioned at an angle 410 relative to a vertical plane 50 substantially parallel to a lens of a camera 5 such that imaging of the camara 5 directly through the glass stack 401 may be distorted. The coated glass assembly 400 can include the glass stack 401 having an inner glass 402, an outer glass 403, and interlayers 404. The coated glass assembly 400 can also include a transparent window separator 35 and a glareshield 36.

In various embodiments, the glass stack 401 can be configured to be modular. The glass stack 401 may have a cutout area 405 around a FOV of the camera 5. The glass stack 401 can have a cutout area formed of different material(s) than the rest of the glass stack 401. A window of the glass stack 401 may be cut out and installed with a glass module 451 to reduce imaging distortion of the camera 5 through the cutout area 405. In some embodiments, the glass module 451 can have an inner glass 452, an outer glass 453, and interlayers 454. The glass module 451 may also be monolithic. In some embodiments, sealant 408 can be used to close a gap between the glass stack 401 and the glass module 451. In some embodiments, the glass module 451 can similarly include a heating element/layer and/or AR coating.

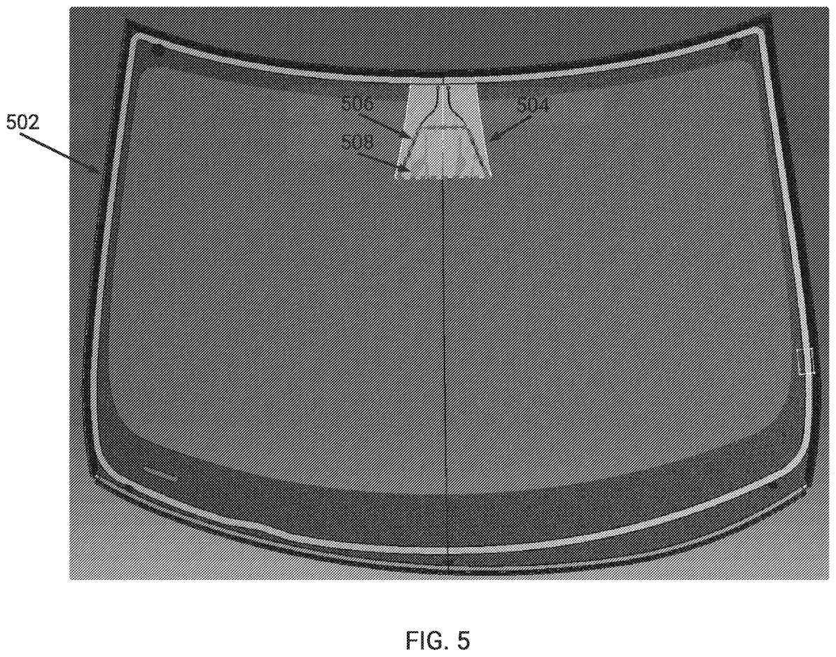

FIG. 5 illustrates a windshield 502 (e.g., glass stack 1 described above) of a vehicle which includes a glass insert 504 (e.g., glass insert 10 described above) according to the techniques described herein. The windshield 502 may be part of a vehicle, such as the front windshield of the vehicle. As illustrated, the glass insert has a field of view portion 506 in which a coated area 508 (e.g., ITO coated area 13 described above) is included.

Although the illustrated embodiments above are all flat, various embodiments of a coated glass assembly can include a curved glass stack (e.g., a curved vehicle windshield) and a coated glass insert coupled to the curved glass stack and configured to conform to the curved glass stack, for example, by cold bending.

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, a person of ordinary skill in the art will recognize that changes may be made in form and detail without departing from the scope of the present disclosure. Thus, the present disclosure is limited only by the claims.

In the foregoing specification, the disclosure has been described with reference to specific embodiments. However, as one skilled in the art will appreciate, various embodiments disclosed herein can be modified or otherwise implemented in various other ways without departing from the spirit and scope of the disclosure. Accordingly, this description is to be considered as illustrative and is for the purpose of teaching those skilled in the art the manner of making and using various embodiments of the disclosed glass assembly. It is to be understood that the forms of disclosure herein shown and described are to be taken as representative embodiments. Equivalent elements, materials, processes or steps may be substituted for those representatively illustrated and described herein. Moreover, certain features of the disclosure may be utilized independently of the use of other features, all as would be apparent to one skilled in the art after having the benefit of this description of the disclosure. Expressions such as “including,” “comprising,” “incorporating,” “consisting of,” “have,” “is” used to describe and claim the present disclosure are intended to be construed in a non-exclusive manner, namely allowing for items, components or elements not explicitly described also to be present. Reference to the singular is also to be construed to relate to the plural.

Further, various embodiments disclosed herein are to be taken in the illustrative and explanatory sense, and should in no way be construed as limiting of the present disclosure. All joinder references (e.g., attached, affixed, coupled, connected, and the like) are only used to aid the reader's understanding of the present disclosure, and may not create limitations, particularly as to the position, orientation, or use of the systems and/or methods disclosed herein. Therefore, joinder references, if any, are to be construed broadly. Moreover, such joinder references do not necessarily infer that two elements are directly connected to each other. Additionally, all numerical terms, such as, but not limited to, “first,” “second,” “third,” “primary,” “secondary,” “main” or any other ordinary and/or numerical terms, should also be taken only as identifiers, to assist the reader's understanding of the various elements, embodiments, variations and/or modifications of the present disclosure, and may not create any limitations, particularly as to the order, or preference, of any element, embodiment, variation and/or modification relative to, or over, another element, embodiment, variation and/or modification.

It will also be appreciated that one or more of the elements depicted in the drawings/figures can also be implemented in a more separated or integrated manner, or even removed or rendered as inoperable in certain cases, as is useful in accordance with a particular application.

What is claimed is:

1. A coated glass assembly configured to be positioned in front of an image sensor, comprising:
a glass stack;
a glass insert coupled to the glass stack via transparent adhesive; and
a transparent conductive layer coated to the glass insert,
wherein the glass insert is configured to be positioned in front of the image sensor.

2. The coated glass assembly of claim 1, wherein the glass stack comprises an outer glass, one or more interlayers, and an inner glass.

3. The coated glass assembly of claim 1, further comprising an anti-reflective coating on the glass insert.

4. The coated glass assembly of claim 1, further comprising conductive traces configured to provide power to the transparent conductive layer and heat up the transparent conductive layer.

5. The coated glass assembly of claim 1, wherein the transparent conductive layer comprises indium tin oxide.

6. A coated glass assembly configured to be positioned in front of an image sensor, comprising:
a glass stack positioned at an angle from a vertical plane, the vertical plane being substantially parallel to a lens of the image sensor;
a first area in the glass stack having a different composition than a second area of the glass stack;
a glareshield extending from a first point proximate a lower end of the first area to a second point proximate the image sensor; and
a window separator positioned parallel to the vertical plane, between the glass stack and the image sensor.

7. The coated glass assembly of claim 6, wherein the glass stack in the second area comprises a first outer glass, a first set of one or more interlayers, and a first inner glass.

8. The coated glass assembly of claim 7, wherein the glass stack in the first area does not comprise the first set of one or more interlayers and the first inner glass.

9. The coated glass assembly of claim 8, wherein the image sensor is mounted to the glass stack through a bracket mounted to an inner surface of the first inner glass in the second area

10. The coated glass assembly of claim 8, wherein the glass stack in the first area comprises a second inner film coupled to the first outer glass via a transparent adhesive.

11. The coated glass assembly of claim 7, wherein the glass stack in the first area comprises a second outer glass different from the first outer glass, a second set of one or more interlayers different from the first set of one or more interlayers, and a second inner glass different from the first inner glass.

12. A glass insert configured for attachment to a glass stack via transparent adhesive, the glass insert being configured to be positioned in front of an image sensor, wherein the glass insert comprises a transparent conductive layer coated thereon, and wherein the transparent conductive layer is within a field of the view of the image sensor.

13. The glass insert of claim 12, wherein the glass insert further comprises an anti-reflective coating.

14. The glass insert of claim 12, wherein the glass stock further comprises conductive traces configured to provide power to the transparent conductive layer and heat up the transparent conductive layer.

15. The glass insert of claim 12, wherein the transparent conductive layer comprises indium tin oxide.
